(19) United States
(12) Patent Application Publication
(10) Pub. No.: US 2012/0200436 A1
(43) Pub. Date: Aug. 9, 2012

(54) Method for Power Reduction in Data Serialization/De-serialization Using Data Pre-load Scheme

(76) Inventor: Hui Wang, Arlington, TX (US)

(21) Appl. No.: 13/021,679

(22) Filed: Feb. 4, 2011

(51) Int. Cl. H03M 9/00

(52) U.S. Cl. 341/100; 341/101

(57) ABSTRACT

A method is provided for saving power in 1:N serializer and N:1 de-serializer by pre-loading the state of shift registers. Pre-loading the last stage of N shift registers with the last parallel data bit value in the multiplexor minimizes state changes in shift registers in the serializer. Pre-loading the 1^{st} stage of N shift registers with the last bit data value in the previous N-bit serial data bit value in the de-multiplexor minimizes state changes in shift registers in the de-serializer. Power consumption can be significantly saved due to minimized number of state changes.

### TECHNICAL FIELD

This invention is related to the field of data serialization/de-serialization in data communication, more specifically, to pre-load data multiplexor/de-multiplextor with data pattern to minimize shift register state changes and therefore reduce power consumption associated with N:1 or 1:N data serialization or de-serialization, where N is the multiplexing/de-multiplexing ratio.

### DISCUSSION OF RELATED ART

Modern high-speed data communication system designs have widely adopted data serialization and de-serialization technology. It offers higher data rate, better reliability, lower noise generation, higher noise immunity and lower power cost. Multiple parallel data bits are multiplexed into one serial data stream in the transmitter, and the serial data stream is de-multiplexed into multiple parallel data bits in the receiver.

The serializer and de-serializer can consist of M stages of multiplexor and de-multiplexor. Each stage of multiplexor or de-multiplexor can have the same multiplex ratio of N₀ to make N₀^{M} multiplex and de-multiplex ratio. Each stage of multiplexor or de-multiplexor can also have different multiplex ratio Nᵢ to make a total of N₁N₂N₃ . . . N_{M} multiplex and de-multiplex ratio. For multiplex ratio other than 2, a parallel load and serial shift architecture is commonly used. For de-multiplex ratio other than 2, a serial shift and parallel load architecture is commonly used.

Digital gates with rail-to-rail voltage swing are normally utilized to construct multiplexor and de-multiplexor. Power consumption in digital gates with rail-to-rail voltage swing is proportional to CVf² if transient short-circuit switching power consumption is not considered. C is the load capacitance of the digital gate, V is the power supply and f is the frequency the digital gates operate at.

### SUMMARY

Consistent with embodiments of the present invention, methods of a preload multiplexing de-multiplexing scheme is provided. In some embodiments, a scheme consisting of a series of N back-to-back connected shift registers; in the serializer, conducting a parallel load to load N-bit data into the N shift registers and then N serial shifts to multiplex N-bit parallel data input into 1-bit serial data output; in the de-serializer, conducting N serial shifts to shift N-bit serial data into N shift registers and a parallel load to de-multiplex 1-bit serial data input into N-bit parallel de-data outputs; pre-loading the last stage of N shift registers with the last parallel data bit value in the multiplexor and pre-loading the stages of N shift registers with the last data bit value in the previous N-bit serial data in the de-multiplexor. During the shift operation, the stages in multiplexor after the last valid data bit does not change state and the stages in de-multiplexor before the first valid data bit does not change state. On average, half of the shift registers in multiplexor or de-multiplexor do not consume power because of un-changed state. Significant power consumption can be saved.

### BRIEF DESCRIPTION OF THE DRAWINGS

Embodiments of this invention will be described in detail below with reference to the accompanying drawings. This invention may, however, be embodied in many different forms and should not be construed as being limited to the embodiments set forth herein.

FIG. 1 shows a diagram illustrating a multi-stage data serializer and de-serializer.

FIG. 2 illustrates an example of N:1 multiplexor consisting of N-bit shift registers

FIG. 3 illustrates an example of 1:N de-multiplexor consisting of N-bit shift registers

FIG. 4 illustrates a diagram of preloading multiplexor

FIG. 5 illustrates a diagram of preloading de-multiplexor

### DETAILED DESCRIPTION

In the following description, specific details are set forth describing the embodiments disclosed herein. It will be apparent, however, to one skilled in the art that some embodiments may be practiced without some or all of these specific details. The specific embodiments disclosed herein are meant to be illustrative but not limiting. One skilled in the art may realize other material that, although not specifically described therein, is within the scope and the spirit of this disclosure.

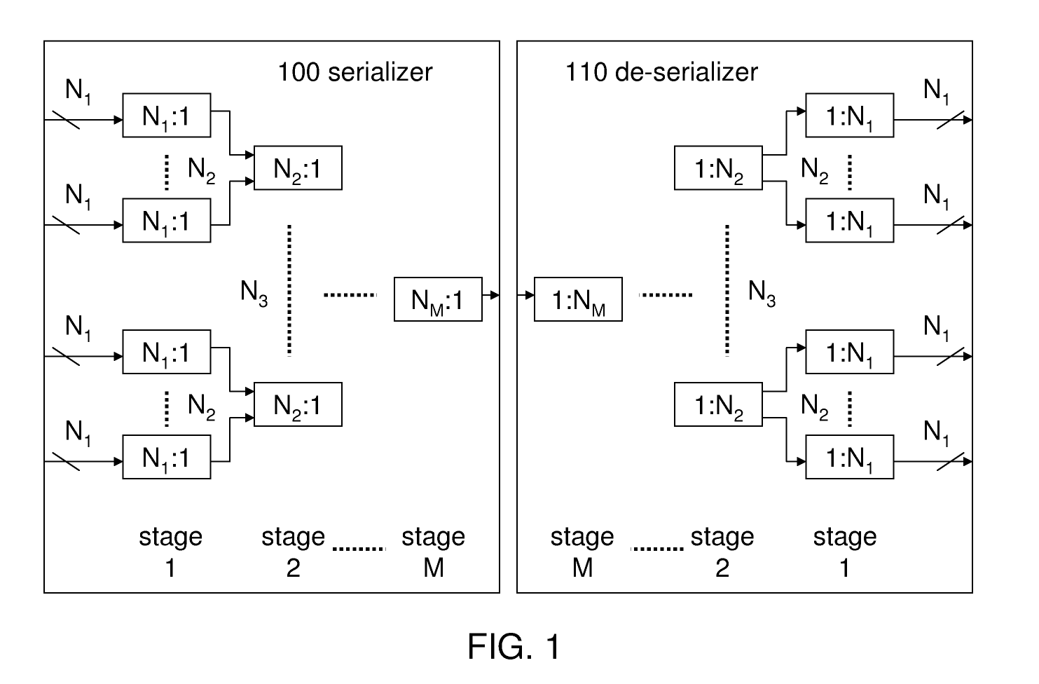

FIG. 1 illustrates a multi-stage 1:N and N:1 serializer and de-serializer. Generally, a serializer 100 consists of M stages of multiplexors with multiplex ratio of Nᵢ for the ith stage. The total multiplex ratio N is the product of multiplex ratio of each stage, N₁N₂ . . . N_{M}. Parallel data of N bits are serialized through the M-stage multiplexor into a 1-bit serial data stream with data baud rate N times that of the parallel data. The de-serializer 110 consists of M stages of de-multiplexors with de-multiplex ratio of Nᵢ for the ith stage. It reverses the operation of the serializer. The total de-multiplex ratio N is the product of de-multiplex ratio of each stage, N₁N₂ . . . N_{M}. Serial data stream of 1 bit is de-serialized through the M-stage de-multiplexor into an N-bit parallel data but with data baud rate 1/N times that of the serial data.

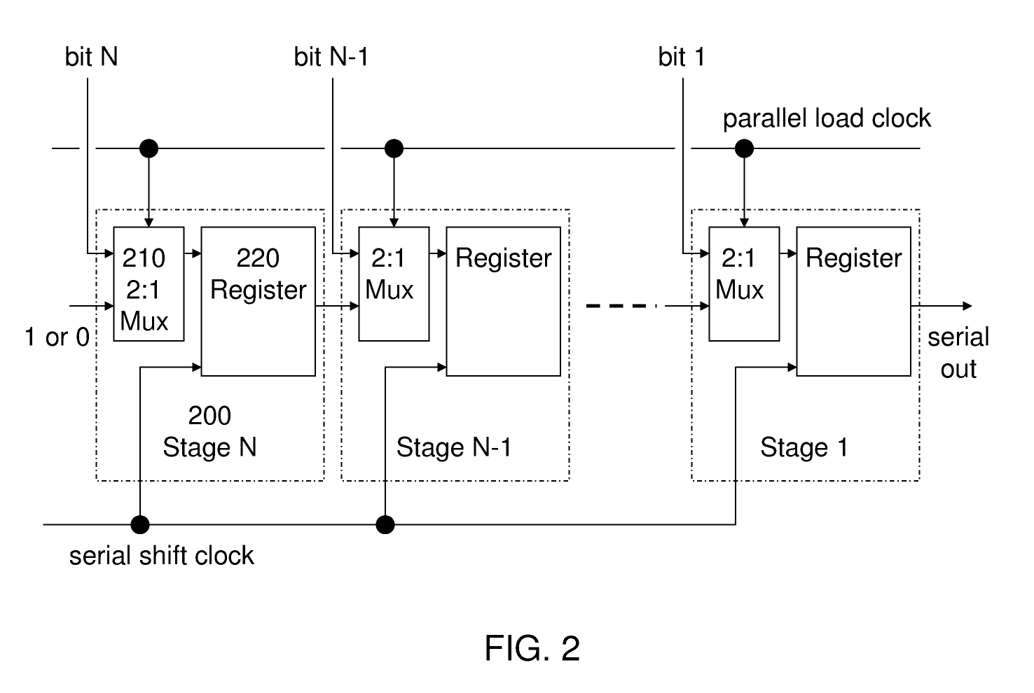

FIG. 2 illustrates an N:1 multiplexor consisting of N stages of shift cell 200. Each stage of shift cell consists of a 2:1 Mux 210 and a register 220. At each load cycle, N-bit parallel data is loaded into N shift registers simultaneous. Then the data in each shift registers is serially shifted out by a serial clock running at N-times the load clock speed. After the last bit of the N-bit data is shifted out, the next load cycle starts and the next N-bit parallel data is loaded into N shift registers. Through this parallel load and serial shift operation, N-bit parallel data is serialized into 1-bit serial data stream running at N-times faster. The input to the last stage of shift registers is normally connected to either “1” or “0”.

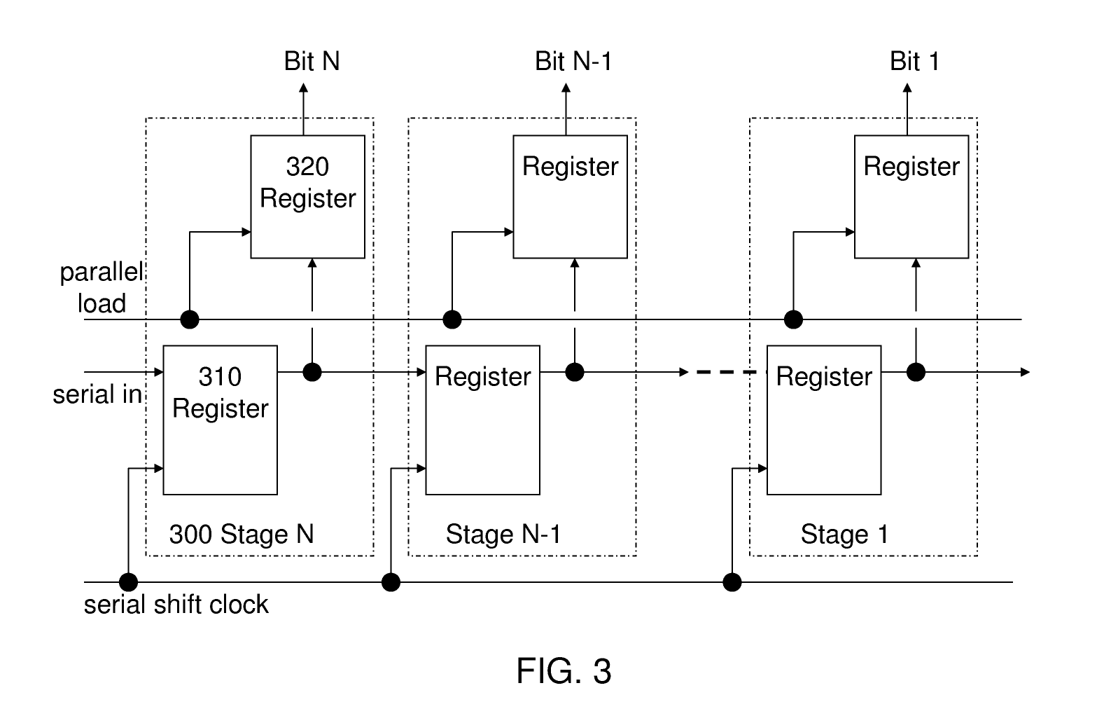

FIG. 3 illustrates a 1:N de-multiplexor consisting of N shift cell 300. Each stage of shift cell consists of serial shift register 310 and parallel data register 320. The serial data stream is shifted into N shift registers by a serial clock running at N-times the load clock speed. After the last bit of the N-bit data is shifted in, data in N shift registers are loaded out simultaneously by the load clock. Then the next serial shift cycle starts and the next N-bit serial data is shifted into N shift registers. Through this serial shift and parallel load operation, 1-bit serial data stream is de-serialized into N-bit parallel data running at 1/N-times faster. As the next N-bit serial data is shifted in, the previous N-bit serial data is shifted out.

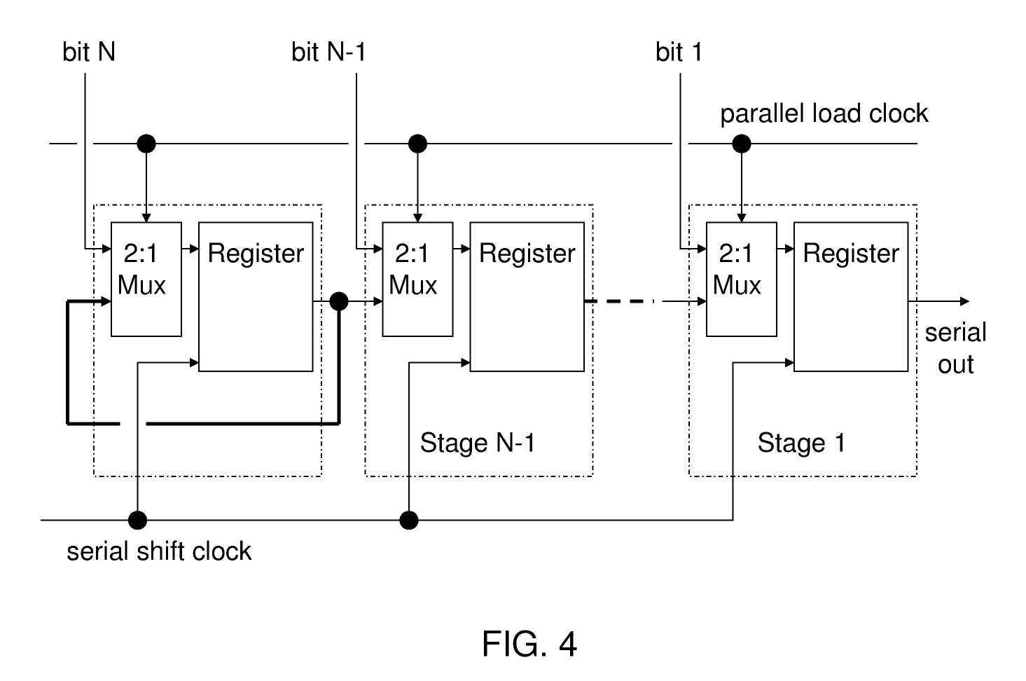

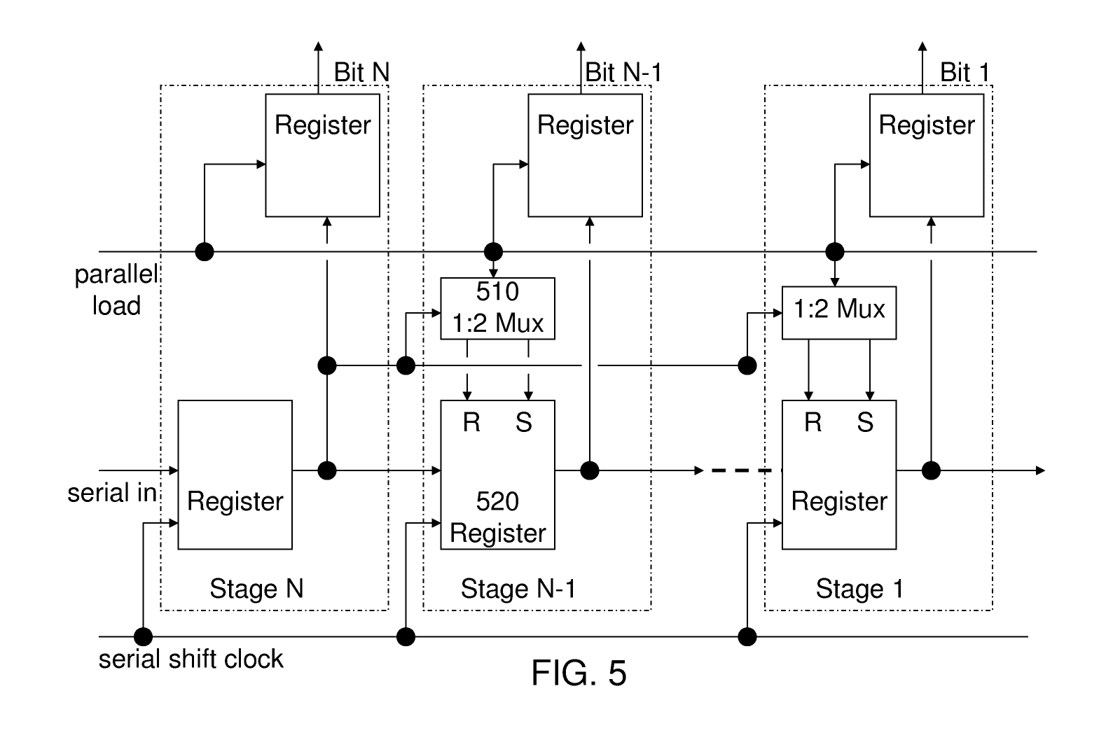

50% of the chance, the last bit of parallel data in the serializer is different from the input of the last stage shift register if the input to the last stage is a constant “0” or “1”. As N-bit data is shifted out in the serializer, each shift register toggles its state as the last bit shifts through. Each state change incurs power consumption. In the de-serializer, the previous N-bit serial data is shifted out as the next N-bit serial data is shifted in. The information from the previous N-bit serial data is not needed after the N-bit data is loaded out in parallel. As the previous N-bit serial data shifts out, each shift register switches its state 50% of the time. Each state change incurs power consumption. In order to save this unnecessary power consumption, a pre-loading scheme is disclosed in this invention. FIG. 4 illustrates an implementation example of the pre-loading scheme in a serializer. The input to the last stage shift register N is loaded with the data value of the last bit in the N-bit parallel data during the serial shift operation. As the serializer shifts out the N-bit parallel data serially, the states of shift registers after the last bit are unchanged. No power consumption is incurred from shift registers beyond the last bit. FIG. 5 illustrates an implementation example of the pre-loading scheme in the de-serializer. Each shift cell has a 1:2 multiplexor 510 controlled by the state of shift register in stage N. Shift register 520 in stages N−1 and beyond are reset (R) and set (S) registers. When the parallel load signal is enabled, the states of shift registers are set to the last bit value of the previous N-bit serial data. As the next N-bit serial data is shifted in, the states of shift registers before the last data bit of the previous N-bit serial data are unchanged. No power consumption is incurred from shift registers beyond the last bit.

Some embodiments of the current invention apply to pre-loading partial shift registers in the de-serializer to the same value as the last bit value to make de-multiplexing timing easy to implement.

Some other embodiments may include pre-loading the shift registers in the de-serializer with a constant “0” or “1” instead of the last bit value. This simplifies the pre-load implementation.

The foregoing description is intended to illustrate, but not to limit, the scope of the invention, which is defined by the scope of the appended claims. Other embodiments are within the scope of this disclosure.

What is claimed is:

1. A method of pre-loading shift registers in 1:N serializer and N:1 de-serializer comprising,
N back-to-back connected shift registers; and
pre-loading the last stage of shift registers in the serializer with the last bit data value of the N-bit parallel data; and
pre-loading the stages of shift registers in the de-serializer with the last bit data value of the previous N-bit serial data;
wherein the number of shift registers in the de-serializer setting to the last bit data value does not need to include all available shift registers.

2. A method of claim 1, wherein the state of the shift registers in the de-serializer can be set to a constant “0” or “1” instead of the last bit data value.

3. A method of claim 1, wherein the state of the shift registers in the de-serializer can be set to the same value to avoid power consumption due to state changes during shift operation.
